(19) United States
(12) Patent Application Publication
(10) Pub. No.: US 2011/0232762 A1
(43) Pub. Date: Sep. 29, 2011

(54) METHOD FOR MANUFACTURING PHOTOELECTRIC CONVERSION ELEMENT, AND PHOTOELECTRIC CONVERSION ELEMENT AND THIN-FILM SOLAR CELL

(75) Inventor: Naoki MURAKAMI, Ashigara-kami-gun (JP)

(73) Assignee: FUJIFILM CORPORATION, Tokyo (JP)

(21) Appl. No.: 13/053,957

(22) Filed: Mar. 22, 2011

(30) Foreign Application Priority Data
Mar. 26, 2010 (JP) 2010-072221
Feb. 22, 2011 (JP) 2011-035763

(51) Int. Cl. H01L 31/0264; H01L 31/0272

(52) U.S. Cl. 136/262; 438/95; 257/E31.008

(57) ABSTRACT

A method for manufacturing a photoelectric conversion element including a step of preparing a substrate and a step of forming a photoelectric conversion layer made of a CIGS-based semiconductor compound on the substrate. The step of forming the photoelectric conversion layer includes exposing the substrate to vapors of (In, Ga) and Se, or a vapor of (In, Ga)_{y}Se_{z}, and is achieved in less than 40 minutes, and the step of exposing the substrate to vapors of (In, Ga) and Se, or vapor of (In, Ga)_{y}Se_{z} includes varying the Ga/(In+Ga) ratio over time.

### BACKGROUND OF THE INVENTION

The present invention relates to a photoelectric conversion element comprising a CIGS (Cu(In, Ga)Se₂) layer as the photoelectric conversion layer, a method for manufacturing same, and a solar cell comprising the photoelectric conversion element. In particular, it relates to a method for manufacturing a photoelectric conversion element wherein formation of the photoelectric conversion layer is accomplished in less than 40 minutes, and a photoelectric conversion element produced by this production method and a solar cell that comprises it.

Recently, intensive research is being conducted in solar cells. A solar cell has a laminated structure in which a semiconductor photoelectric conversion layer that generates current by light absorption is sandwiched between a back electrode and a transparent electrode.

As next-generation solar cells, those that use chalcopyrite-type CuInSe₂ (CIS) or Cu(In, Ga)Se₂ (also referred to as “CIGS” hereinafter) in the photoelectric conversion layer are being studied. Solar cell modules that use CIGS in the photoelectric conversion layer are increasingly being studied because they can be made from thin films due to their relatively high efficiency and high photoabsorptivity.

In solar cells that use CIGS in the photoelectric conversion layer, for example, a p-type CIGS layer is formed as a photoelectric conversion layer on a back electrode, an n-type CdS layer is formed on the p-type CIGS layer, and a transparent electrode is formed on the CdS layer. A p-n junction is formed by the p-type CIGS layer and the n-type CdS layer. As of today, various methods of forming CIGS layers used in photoelectric conversion layers have been proposed (refer to JP 3130943 B, JP 3202886 B).

JP 3130943 B has the objective of providing a method for manufacturing a good-quality Cu(In, Ga)Se₂ thin film. JP 3130943 B describes a method for forming a Cu(In, Ga)Se₂ thin film by a step of producing a phase-separated compound mixture made of Cu(In, Ga)Se₂: CuₓSe containing a large amount of Cu on a base, and a step of transforming the CuₓSe in this mixture to Cu_{w}(In, Ga)_{y}Se_{z} by exposing CuₓSe to (In, Ga) and Se, or to (In, Ga)_{y}Se_{z}. Note that it is disclosed that transformation from CuₓSe to Cu_{w}(In, Ga)_{y}Se_{z} is preferably performed at an elevated temperature in the range of 300° C. to 600° C.

JP 3202886 B has the objective of providing a method for manufacturing, with good reproducibility, a high-quality ABC₂ chalcopyrite-type thin film that can be used in photoelectric conversion elements such as thin-film solar cells.

Note that in an ABC₂ chalcopyrite-type thin film, A is Cu or Ag, B is In, Ga or Al, and C is S, Se or Te.

The method for manufacturing an ABC₂ chalcopyrite-type thin film of JP 3202886 B comprises: a first step of forming a thin film containing element A, element B and element C, with element A being in excess of the stoichiometric ratio of ABC₂, on a heated substrate; a second step of exposing this thin film to flux or gas containing element B and element C, or flux or gas containing element A, element B and element C with element B being in excess of the stoichiometric ratio of ABC₂; and a step of monitoring the physical characteristics of the thin film, which vary in response to changes in the ratio of element A to element B (A/B) in the thin film. In JP 3202886 B, the physical characteristics of the thin film vary uniquely as the A/B ratio in the thin film varies from excess element A to the stoichiometric ratio of ABC₂, and when the composition reaches an excess of element B, it becomes saturated, and in JP 3202886 B, the second step is stopped when the physical characteristics of the thin film indicate the saturation value.

If the film formation time of the CIGS layer is sufficiently long, even if the proportion of Ga with respect to (In+Ga) in the exposure vapor, that is, the Ga/(In+Ga) ratio, is not varied, a CIGS layer is formed wherein the Ga/(In+Ga) ratio spontaneously changes in a direction of thickness of the CIGS layer since diffusion of Ga in the CIGS layer is slower than that of In.

However, if the film formation time is less than 40 minutes, In and Ga cannot diffuse sufficiently, and the CIGS layer ends up having a constant ratio of Ga/(In+Ga) in the direction of thickness. As shown in FIG. 4, the conversion efficiency decreases, with a boundary of film formation time of 40 minutes.

As shown in FIG. 5B, when a CIGS layer produced with a film formation time of 40 minutes was analyzed by SIMS (secondary ion mass spectrometry), the proportion of the minimum ion count of Ga with respect to the maximum value (referred to as “proportion of Ga” hereinafter) was 85%.

On the other hand, in a CIGS layer whose film formation time is 90 minutes, in the results of SIMS analysis as shown in FIG. 5C, the proportion of Ga is 60%. Note that in a CIGS layer whose film formation time is 10 minutes, in the results of SIMS analysis as shown in FIG. 5A, the proportion of Ga is 90%, and the Ga distribution is substantially flat.

As described above, if the film formation time is long, such as 90 minutes, for example, the proportion of Ga is 60%, which is greater than in other cases, because Ga can fully diffuse. In contrast, if film formation time is short, as shown in FIG. 5B and FIG. 5A, the proportion of Ga is small and the Ga distribution is substantially flat.

In JP 3130943 B and JP 3202886 B, when the film formation time is less than 40 minutes, a CIGS layer is formed having a constant Ga/(In+Ga) ratio in the direction of thickness because the Ga/(In+Ga) ratio is not varied during film formation of the CIGS layer. For this reason, in JP 3130943 B and JP 3202886 B, there is the problem that conversion efficiency cannot be improved by varying the bandgap (Eg) in the direction of thickness of the CIGS layer. Thus, the current state of the art is such that a photoelectric conversion layer having high conversion efficiency cannot be formed if the film formation time is a short 40 minutes.

The objective of the present invention is to solve the above-described problems of prior art, and to provide a method for manufacturing a photoelectric conversion element having excellent photoelectric conversion efficiency, wherein the bandgap (Eg) in the direction of thickness of the photoelectric conversion layer can be varied, and a photoelectric conversion element produced by this production method, and a thin-film solar cell comprising this photoelectric element.

### SUMMARY OF THE INVENTION

To achieve the above-described objective, a first aspect of the present invention provides a method for manufacturing a photoelectric conversion element comprising a step of preparing a substrate and a step of forming a photoelectric conversion layer made of a CIGS-based semiconductor compound on the substrate, wherein the step of forming the photoelectric conversion layer includes exposing the substrate to vapors of (In, Ga) and Se, or a vapor of (In, Ga)_{y}Se_{z}, and is achieved in less than 40 minutes, and wherein the step of exposing the substrate to vapors of (In, Ga) and Se, or vapor of (In, Ga)_{y}Se_{z} includes varying the Ga/(In+Ga) ratio over time.

Preferably, the step of forming the photoelectric conversion layer is carried out in a temperature range of 500° C. to 650° C.

In the step of exposing the substrate to vapors of (In, Ga) and Se, or vapor of (In, Ga)_{y}Se_{z}, varying the Ga/(In+Ga) ratio over time means, for example, reducing the Ga/(In+Ga) ratio as of the initial stage of formation of the photoelectric conversion layer.

In the step of exposing the substrate to vapors of (In, Ga) and Se, or vapor of (In, Ga)_{y}Se_{z}, varying the Ga/(In+Ga) ratio over time means, for example, reducing the Ga/(In+Ga) ratio as of the initial stage of formation of the photoelectric conversion layer and then increasing the Ga/(In+Ga) ratio.

The substrate is preferably an insulating substrate. For example, the insulating substrate may be formed using a glass sheet, a glass sheet coated with molybdenum, an anodized aluminum sheet, or a base in which the anodized film of an anodized aluminum sheet is coated with molybdenum, or a polyimide base or polyimide base coated with molybdenum.

A second aspect of the present invention provides a method for manufacturing a photoelectric conversion element, comprising: a step of preparing a substrate and a step of forming a photoelectric conversion layer made of a CIGS-based semiconductor compound on the substrate, wherein the step of forming a photoelectric conversion layer includes a first step of forming a phase-separated compound mixture made of Cu(In, Ga)Se₂: CuₓSe containing a large amount of Cu on the substrate and a second step of transforming CuₓSe to Cu_{w}(In, Ga)_{y}Se_{z} by exposing the CuₓSe in the phase-separated compound mixture to vapors of (In, Ga) and Se, or by exposing the CuₓSe in the phase-separated compound mixture to a vapor of (In, Ga)_{y}Se_{z}, wherein the step of forming a photoelectric conversion layer is accomplished in less than 40 minutes and wherein the second step includes varying the Ga/(In+Ga) ratio over time.

In the second step, varying the Ga/(In+Ga) ratio over time means, for example, reducing the Ga/(In+Ga) ratio as of the initial stage of formation of the photoelectric conversion layer.

Further, in the second step, varying the Ga/(In+Ga) ratio over time means, for example, reducing the Ga/(In+Ga) ratio as of the initial stage of formation of the photoelectric conversion layer, and then increasing the Ga/(In+Ga) ratio.

Further, the first step is preferably carried out in a temperature range of 500° C. to 650° C., and the second step is preferably carried out in a temperature range of 500° C. to 650° C.

The second step preferably includes a step of transforming the CuₓSe to Cu(In, Ga)Se₂.

Further, in the CuₓSe, x preferably has a value such that 1≦x≦2.

Further, the ratio of Cu(In, Ga)Se₂: CuₓSe is preferably 1:2.

Further, the compound mixture made up of Cu(In, Ga)Se₂: CuₓSe preferably has a Cu content of 40 atomic % to 50 atomic %.

Further, the second step preferably includes a step of exposing the CuₓSe to In_{y}Se_{z}.

Further, the second step preferably includes a step of exposing the CuₓSe to In₂Se₃.

Further, the second step preferably includes a step of exposing the CuₓSe to In vapor and Se vapor.

Further, the first step preferably includes a step of producing the compound mixture by forming the Cu(In, Ga)Se₂ and the CuₓSe on the base.

Further, the first step preferably includes a step of producing the compound mixture by simultaneously forming the Cu(In, Ga)Se₂ and the CuₓSe on the base.

Further, the first step preferably includes a step of producing the compound mixture by sequentially forming the Cu(In, Ga)Se₂ and the CuₓSe on the base.

Further, the first step preferably includes a step of producing the compound mixture by forming the CuₓSe and In_{y}Se_{z}.

In this case, the first step preferably includes a step of producing the compound mixture by sequentially forming the CuₓSe and In_{y}Se_{z}.

In this case, the first step preferably includes a step of producing the compound mixture by simultaneously forming the CuₓSe and In_{y}Se_{z}.

Note that in the CuₓSe, x preferably has a value such that 1≦x≦2, and in the In_{y}S_{z}, y is preferably 2 and z is preferably 3.

Further, the substrate is preferably an insulating substrate. For example, as the insulating substrate, a glass sheet, a glass sheet coated with molybdenum, an anodized aluminum sheet, or a base in which the anodized film of an anodized aluminum sheet is coated with molybdenum, or a polyimide base or polyimide base coated with molybdenum may be used.

A third aspect of the invention provides a photoelectric conversion element produced by the first method for manufacturing a photoelectric conversion element of the present invention or the second method for manufacturing a photoelectric conversion element of the present invention.

A fourth aspect of the present invention provides a thin-film solar cell that comprises the photoelectric conversion element of the third aspect of the present invention.

According to the present invention, photoelectric conversion efficiency can be improved by varying the bandgap (Eg) in the direction of thickness of the photoelectric conversion layer even when the step of forming a photoelectric conversion layer is less than a short 40 minutes, by varying the Ga/(In+Ga) ratio over time when the substrate is exposed to the vapors of (In, Ga) and Se or vapor of (In, Ga)_{y}Se_{z} in the step of forming a CIGS layer serving as a photoelectric conversion layer. As a result, a photoelectric conversion element and thin-film solar cell having excellent photoelectric conversion efficiency can be obtained at low cost and with high productivity because the film formation time is short.

### BRIEF DESCRIPTION OF THE DRAWINGS

FIG. 1 is a schematic cross-sectional view illustrating a photoelectric conversion element according to an embodiment of the present invention.

FIG. 2 is a schematic cross-sectional view illustrating a film deposition apparatus used in manufacturing of the photoelectric conversion element of an embodiment of the present invention.

FIG. 3A is a graph showing the results of analysis by SIMS (secondary ion mass spectrometry) of a CIGS layer produced by the method for manufacturing a photoelectric conversion element of the present invention, with the secondary ion intensities of copper(Cu), gallium(Ga), selenium(Se), indium(In) and molybdenum(Mo) on the vertical axis, and the depth of the CIGS layer in its thickness direction on the horizontal axis; FIG. 3b is a graph showing the results of analysis by SIMS (secondary ion mass spectrometry) of a CIGS layer produced by a method for manufacturing a conventional photoelectric conversion element, with the secondary ion intensities of copper, gallium, selenium, indium and molybdenum on the vertical axis, and the thickness of the CIGS layer on the horizontal axis.

FIG. 4 is a graph illustrating the change in conversion efficiency according to film formation time, with conversion efficiency on the vertical axis and film formation time on the horizontal axis.

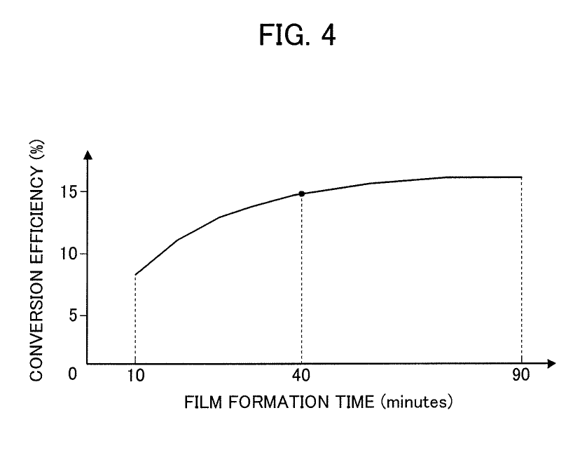

FIG. 5A is a graph showing the results of analysis by SIMS (secondary ion mass spectrometry) of a CIGS layer having a film formation time of 10 minutes, with the secondary ion intensity of gallium (Ga) on the vertical axis, and the thickness of the CIGS layer on the horizontal axis; FIG. 5B is a graph showing the results of analysis by SIMS (secondary ion mass spectrometry) of a CIGS layer having a film formation time of 40 minutes, with the secondary ion intensity of gallium on the vertical axis, and the thickness of the CIGS layer on the horizontal axis; FIG. 5C is a graph showing the results of analysis by SIMS (secondary ion mass spectrometry) of a CIGS layer having a film formation time of 90 minutes, with the secondary ion intensity of gallium on the vertical axis, and the thickness of the CIGS layer on the horizontal axis.

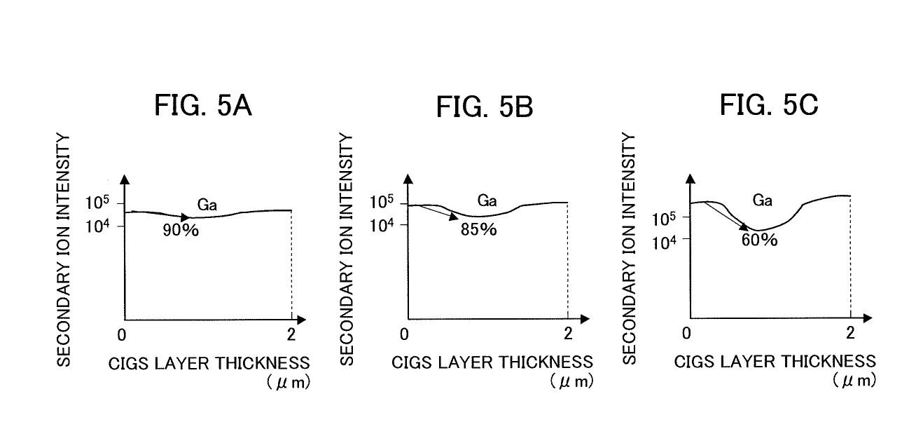

### DETAILED DESCRIPTION OF THE INVENTION

The method for manufacturing a photoelectric conversion element, the photoelectric conversion element and the thin-film solar cell of the present invention will now be described in detail based on preferred embodiments illustrated in the accompanying drawings.

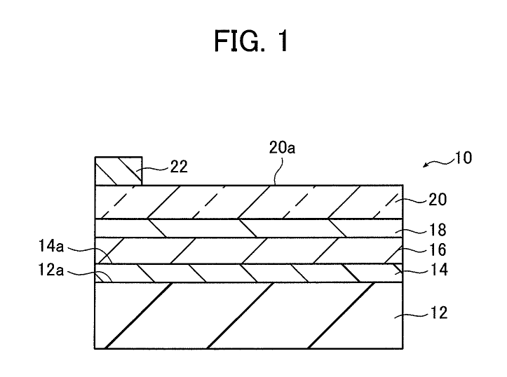

FIG. 1 is a schematic cross-sectional view illustrating a photoelectric conversion element according to an embodiment of the present invention.

The photoelectric conversion element 10 of the embodiment illustrated in FIG. 1 is an example of a photoelectric conversion element produced by the method for manufacturing a photoelectric conversion element described below. For this reason, the configuration of the photoelectric conversion element produced by the method for manufacturing a photoelectric conversion element of the present invention is not limited to that illustrated in FIG. 1.

The photoelectric conversion element 10 comprises an insulating substrate 12 (referred to simply as “substrate 12” hereinafter), a back electrode 14 formed on a surface 12a of the substrate 12, a photoelectric conversion layer 16 formed on a surface 14a of the back electrode 14, a buffer layer 18 formed on the photoelectric conversion layer 16, a transparent electrode 20 formed on the buffer layer 18, and a collector electrode 22 formed on the transparent electrode 20.

As the substrate 12 of this embodiment, one that maintains a predetermined strength even when exposed to high temperature is used, as it may be exposed to high temperatures exceeding 400° C. during formation of the photoelectric conversion layer 16 when the photoelectric conversion element 10 is produced. As the substrate 12, for example, glass sheets such as soda lime glass, high strain point glass or non-alkali glass may be used. Further, the various glass sheets described above which have been coated with molybdenum may be used as the substrate 12.

An anodized aluminum sheet may be used as the substrate 12. Additionally, a base in which the anodized film of an anodized aluminum sheet has been coated with molybdenum may be used as the substrate 12. Also, a polyimide base may be used as the substrate 12. Further, a polyimide base that has been coated with molybdenum may also be used as the substrate 12. Note that when the substrates that have been coated with molybdenum as described above are used, the coated molybdenum serves as the back electrode.

Additionally, a substrate with an insulation layer in which an electrically insulating layer is formed on the surface of a metal substrate described in detail below may also be used as the substrate 12. As this substrate with an insulation layer, although described in detail below, one made of JIS 1N99 material (purity 99.99 mass %) 300 μm in thickness which has been anodized to form an anodized film having a porous structure having a thickness of 5 μm may be used.

As the anodization treatment, for example electrolysis treatment is carried out for 5 minutes under constant voltage conditions at voltage of 40 V in an electrolytic bath, using an oxalic acid aqueous solution having a temperature of 55° C. and concentration of 1 mol/L as the electrolytic bath. Note that during anodization treatment, the current density is not particularly regulated, but it is approximately 10 A/dm² as an average value during the anodization treatment.

Note that in the anodization treatment, for example, NeoCool BD36 (made by Yamato Scientific Co., Ltd.) may be used as the cooling apparatus, pair stirrer PS-100 (made by EYELA) may be used as the stirring and heating apparatus, and GP0650-2R (made by Takasago Ltd.) may be used as the power source.

The substrate 12 of this embodiment has the form of a flat sheet, for example, and its shape and size, etc., are appropriately determined according to the size, etc., of the photoelectric conversion element 10 in which it is used.

The back electrode 14 is formed, for example, of molybdenum, chromium or tungsten, or a combination thereof. The back electrode 14 may have a single-layer structure or a laminated structure such as a two-layer structure. The back electrode 14 is preferably made of molybdenum.

Further, the method for forming the back electrode 14 is not particularly limited, and it may be formed by a vapor-phase film formation method such as electron beam vapor deposition or sputtering, for example.

The back electrode 14 is generally about 800 nm thick, and the back electrode 14 is preferably 400 nm to 1000 nm (1 μm) thick.

The photoelectric conversion layer 16 has a photoelectric conversion function, such that it generates current by absorbing light that has reached it through the transparent electrode 20. The photoelectric conversion layer 16 will be described in detail later.

The buffer layer 18 is formed to protect the photoelectric conversion layer 16 when forming the transparent electrodes 20 and to allow the light impinging on the transparent electrodes 20 to enter the photoelectric conversion layer 16.

The buffer layer 18 is constructed from a compound that includes at least a group IIb element and a group VIb element, such as CdS, Zn(O, S, OH) or In(S, OH), for example. The buffer layer 18 forms a p-n junction layer with the photoelectric conversion layer 16.

The buffer layer 18 preferably has a thickness of 20 nm to 100 nm, for example. The buffer layer 18 is formed by, for example, chemical bath deposition (CBD) method.

The transparent electrodes 20 are formed, for example, of ZnO doped with aluminum(Al), boron(B), gallium(Ga), indium(In), etc., or ITO (indium tin oxide). The transparent electrodes 20 may have a single-layer structure or a laminated structure such as a two-layer structure. The thickness of the transparent electrodes 20, which is not specifically limited, is preferably 0.3 μm to 1 μm.

Further, the method for forming the transparent electrode 20 is not particularly limited; it may be formed by coating techniques or vapor-phase deposition techniques such as electron beam vapor deposition and sputtering.

The collector electrode 22 is formed on a surface 20a of the transparent electrode 20, local to the transparent electrode 20 and in a rectangular shape, for example. The collector electrode 22 is an electrode for taking out current produced in the photoelectric conversion layer 16 from the transparent electrode 20. Further, the collector electrode 22 is made of aluminum, for example. The collector electrode 22 is formed, for example, by sputtering, vapor deposition, etc.

The photoelectric conversion layer 16 will now be described.

The photoelectric conversion layer 16 is made of a CIGS-based semiconductor compound; for example, it is made of Cu(In, Ga)Se₂ having a chalcopyrite crystal structure. The photoelectric conversion layer 16 has high photoabsorptivity and high photoelectric conversion efficiency because it has a chalcopyrite crystal structure. Moreover, it has little degradation of efficiency under exposure to light, etc., and exhibits excellent durability.

In the photoelectric conversion layer 16, the bandgap width and carrier mobility, etc., can be controlled by creating a distribution in the amount of Ga in the direction of thickness of the photoelectric conversion layer 16. As a result, the photoelectric conversion layer 16 can be given a single-graded bandgap structure or a double-graded bandgap structure.

The photoelectric conversion layer 16 is formed in less than 40 minutes.

The photoelectric conversion layer 16 is formed by varying the proportion of Ga with respect to (In+Ga) over time, that is, the Ga/(In+Ga) ratio, when exposing the surface 14a of the back electrode 14 formed on the substrate 12 to vapors of (In, Ga) and Se or vapor of (In, Ga)_{y}Se_{z}, and exposing the surface 14a of the back electrode 14 to vapors of (In, Ga) and Se or vapor of (In, Ga)_{y}Se_{z}.

The photoelectric conversion layer 16 is formed, more specifically, by a first step in which a phase-separated compound mixture made of Cu(In, Ga)Se₂:CuₓSe and containing a large amount of Cu is formed on the surface 14a of the back electrode 14, and a second step in which CuₓSe is transformed to Cu_{w}(In, Ga)_{y}Se_{z} by exposing the CuₓSe (1≦x≦2) in this phase-separated compound mixture to vapors of (In, Ga) and Se.

Further, the second step may be a step in which CuₓSe is transformed to Cu_{w}(In, Ga)_{y}Se_{z} by exposing the CuₓSe (1≦x≦2) in this phase-separated compound mixture to vapor of (In, Ga)_{y}Se_{z}.

Note that the ratio of Cu(In, Ga)Se₂: CuₓSe is preferably 1:2.

As described above, in the first step of the photoelectric conversion layer 16, a three-element compound mixture of phase-separated Cu(In, Ga)Se: CuₓSe containing an extremely large amount of Cu is formed on the surface 14a of the back electrode 14 of the substrate 12. In the subsequent second step, CuₓSe is recrystallized.

In the second step, a temperature high enough to maintain a CuₓSe environment containing a large amount of liquid is maintained, and a CuInₓSe_{y} compound is produced by obtaining a precipitate formed by successive precipitation of In and Se, or a precipitate formed by simultaneous precipitation of In and Se, or produced by precipitating a substance containing a large amount of In like two-element In_{y}Se, in an atmosphere of excess Se vapor pressure.

In the first step, the surface 14a of the back electrode 14 formed on the substrate 12 is exposed to vapors of (In, Ga) and Se or a vapor of (In, Ga)_{y}Se_{z}, causing precipitation of CuInSe₂: CuₓSe containing a large quantity of Cu on the substrate 12.

According to a phase diagram not shown, if the mol % of In₂Se₃ is in the range of 0% to 50% and the temperature is approximately 790° C. or below, the CuInSe₂ and CuₓSe phases are separated. Therefore, in an extremely Cu-rich mixture made of, preferably, approximately 40 atomic % to 50 atomic % Cu, CuInSe₂ crystals grow separately from CuₓSe crystals, and CuInSe₂ is phase-separated from CuₓSe, following the precipitation of Cu, In and Se on the back electrode 14 by heating to a temperature of preferably about 500° C. to 550° C.

Here, the melting point of CuₓSe is slightly lower than that of CuInSe₂. For this reason, it is preferred that the substrate 12 is maintained in the temperature range of 500° C. to 550° C. In this case, CuInSe₂ exists as a solid, and CuₓSe exists as a liquid. Also, as the precipitation process continues, the CuInSe₂ crystals grow on the surface 14a of the back electrode 14, such that liquid CuₓSe is excluded to the outside. Also, CuInSe₂ crystals attach to the surface 14a of the back electrode 14, and a layer of liquid CuₓSe is formed on their outer surface.

If CuInSe₂ and CuₓSe are precipitated sequentially or at a lower temperature, solid CuₓSe is transformed to liquid CuₓSe by setting the temperature to approximately 500° C. to 550° C., and it is thought to cause growth or recrystallization in the CuₓSe two-phase liquid environment.

Further, in the second step, if the substrate 12 is maintained at a temperature of approximately 300° C. to 600° C., the excess CuₓSe produced in the first step is transformed to CuIn_{y}Se_{z}, or to In_{y}Se_{z} such as In₂Se₃ which does not contain Cu, due to it being exposed to In vapor and Se vapor. Further, the transformation of CuₓSe to CuIn_{y}Se_{z} may also be performed by successive precipitation of In and Se on the grown or recrystallized CuₓSe.

When the temperature of the substrate 12 is in the range of approximately 500° C. to 600° C., CuₓSe is a liquid, and CuInSe₂ remains as a solid. Indium vapor condenses in the liquid phase on the surface of the CuₓSe. This liquid In vapor and Se vapor come into contact with the liquid CuₓSe and react with excess CuₓSe on its surface, thereby producing CuInSe₂, and CuInSe₂ crystals grow homogeneously. The liquid CuₓSe is substantially consumed, and a CIGS layer is formed.

Note that in the present invention, the Ga/(In+Ga) ratio is varied over time when the CuₓSe in the phase-separated compound mixture is exposed to vapors of (In, Ga) and Se or vapor of (In, Ga)_{y}Se_{z}. This variation over time is carried out specifically, for example, by varying the amount of vaporization of Cu, In, Ga and Se by the timing of opening and closing of shutters provided on the crucibles or by adjusting the temperature during vaporization of Cu, In, Ga and Se.

In the first step, CuInSe₂ and CuₓSe may be simultaneously precipitated or sequentially precipitated. If sequentially precipitated, the order of CuInSe₂ and CuₓSe is not particularly limited.

Further, the first step preferably includes a step of producing a compound mixture by precipitating CuₓSe and In_{y}Se_{z}. In this case, CuₓSe and In_{y}Se_{z} may be simultaneously precipitated or sequentially precipitated. If sequentially precipitated, the order of CuₓSe and In_{y}Se_{z} is not particularly limited.

Additionally, the second step preferably includes a step of exposing CuₓSe to In_{y}Se_{z}. In this case, In_{y}Se_{z} is, for example In₂Se₃.

Further, when forming the photoelectric conversion layer 16, in either the first step or the second step, the temperature of the substrate 12 is, for example, 400° C. or above, and its upper limit is 650° C. Preferably, the temperature of the substrate 12 is 500° C. to 650° C.

In the photoelectric conversion element 10 of this embodiment, the current generated in the photoelectric conversion layer 16 of the photoelectric conversion element 10 is taken outside of the photoelectric conversion element 10 from the back electrode 14 and collector electrode 22. Note that the back electrode 14 is a cathode (negative electrode), and the collector electrode 22 is an anode (positive electrode). Further, the polarities of the back electrode 14 and the collector electrode 22 may be reversed; their polarities may vary according to the configuration of the photoelectric conversion layer 16 and the configuration of the photoelectric conversion element 10, etc.

Further, a bond/seal layer (not shown), a water vapor barrier layer (not shown), and a surface protective layer (not shown) are arranged on the front side of the photoelectric conversion element 10, and a bond/seal layer (not shown) and a back sheet (not shown) are arranged on the back side of the photoelectric conversion element 10, that is, on the back side of the substrate 12, and these layers are unified by a lamination process by, for example, vacuum lamination. A thin-film solar cell may be thus obtained.

Next, the method for manufacturing the photoelectric conversion element 10 of this embodiment will be described.

In the method for manufacturing the photoelectric conversion element 10 of this embodiment, first, a soda lime glass sheet of a predetermined size, for example, is prepared as the substrate 12. As this soda lime glass sheet, one made by ATOK with a thickness of 1 mm, for example, is used.

Subsequently, a molybdenum film, for example, is formed to a thickness of 800 nm on the front surface 12a of the substrate 12 by DC sputtering using a film deposition apparatus, for example, and the back electrode 14 is thereby formed.

Subsequently, the photoelectric conversion layer 16 is formed on the surface 14a of the back electrode 14. The method for forming this photoelectric conversion layer 16 will be described in detail below.

Subsequently, a CdS layer (n-type semiconductor layer) serving as the buffer layer 18 is formed on the photoelectric conversion layer 16 by, for example, chemical bath deposition (CBD) method. As a result, the photoelectric conversion layer 16 and the buffer layer 18 form a p-n junction layer.

Note that the buffer layer 18 is not limited to a CdS layer, and a compound layer that includes at least a group lib element and a group VIb element, such as In(S, OH) or Zn(O, OH, S) may be formed by, for example, CBD method.

Subsequently, for example, a ZnO layer doped with Al, or an ITO layer serving as a transparent electrode 20 is formed to a thickness of 800 nm, for example, by DC sputtering using a film deposition apparatus. The transparent electrode 20 is thus formed.

Subsequently, a collector electrode 22 made of aluminum is formed by, for example, sputtering or vapor deposition on the surface 20a of the transparent electrode 20. The photoelectric conversion element 10 illustrated in FIG. 1 can be thus formed.

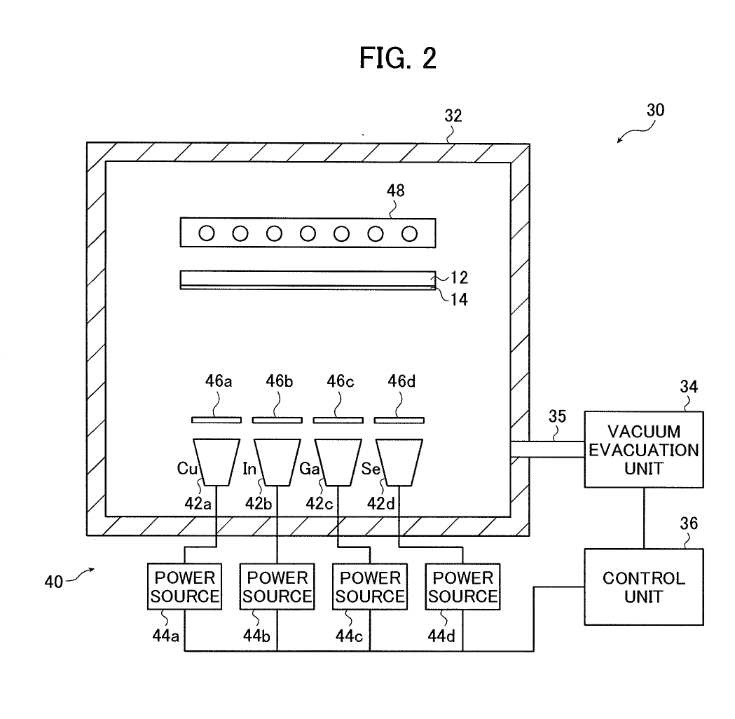

The method for manufacturing the photoelectric conversion layer 16 will now be described. The photoelectric conversion layer 16 is formed by, for example, the film deposition apparatus 30 illustrated in FIG. 2.

The film deposition apparatus 30 illustrated in FIG. 2 is one that uses molecular beam epitaxy (MBE). A vacuum evacuation unit 34 is connected via a pipe 35 to a chamber 32, the inside of which is held at a predetermined degree of vacuum. Although not shown in the drawing, items such as a pressure gauge, etc., with which film deposition apparatuses that use molecular beam epitaxy (MBE) are generally equipped are provided in the chamber 32.

In the film deposition apparatus 30, a film deposition unit 40 is provided, and this film deposition unit 40 comprises a copper (Cu) vapor deposition crucible 42a, an indium (In) vapor deposition crucible 42b, a gallium (Ga) vapor deposition crucible 42c and a selenium (Se) vapor deposition crucible 42d. Each of the vapor deposition crucibles 42a to 42d uses a K-cell (Knudsen cell), for example, and has an aperture. Vapors of Cu, In, Ga and Se, respectively, are released from the apertures of the vapor deposition crucibles 42a to 42d. Each of the vapor deposition crucibles 42a to 42d is provided inside the chamber 32.

Above the vapor deposition crucibles 42a to 42d, shutters 46a to 46d are provided. The shutters 46a to 46d control the vapors from the apertures of the vapor deposition crucibles 42a to 42d reaching the substrate 12, and are provided such that they are opened and closed with respect to the apertures by, for example, a movement mechanism (not shown). The apertures of the vapor deposition crucibles 42a to 42d are opened or closed by the shutters 46a to 46d.

Further, power sources 44a to 44d provided outside the chamber 32 are connected to the vapor deposition crucibles 42a to 42d. By means of the power sources 44a to 44d, the vapor deposition crucibles 42a to 42d are heated to and held at respective predetermined temperatures, and vapors of copper (Cu), indium (In), gallium (Ga) and selenium (Se) are released from the vapor deposition crucibles 42a to 42d.

Further, the power sources 44a to 44d also have the function of increasing or decreasing the temperatures of the vapor deposition crucibles 42a to 42d per unit time, for example. This increase or decrease of temperature per unit time is set and controlled via a control unit 36.

Further, a heating unit 48 which sets the substrate 12 to a predetermined temperature, for example 520° C., is provided inside the chamber 32. As the heating unit 48, a heating apparatus generally used in film deposition apparatuses that use molecular beam epitaxy (MBE) may be employed.

The vacuum evacuation unit 34, power sources 44a to 44d, heating unit 48 and movement mechanism (not shown) are connected to the control unit 36, and the vacuum evacuation unit 34, power sources 44a to 44d, heating unit 48 and movement mechanism (not shown) are controlled by the control unit 36.

Note that as the film deposition apparatus 30, an MBE apparatus made by Epiquest, for example, may be used.

When forming the photoelectric conversion layer 16 using the film deposition apparatus 30, the inside of the chamber 32 is set to a predetermined degree of vacuum by the vacuum evacuation unit 34. Subsequently, the substrate 12 is set to, for example, 520° C., by the heating unit 48. Note that if the substrate 12 is made of a non-metal such as polyimide, the temperature of the substrate 12 by the heating unit 48 is, for example, 400° C.

Subsequently, the temperature of the copper (Cu) vapor deposition crucible 42a is set to, for example, 1300° C., the temperature of the indium (In) vapor deposition crucible 42b is set to, for example, 930° C., the temperature of the gallium (Ga) vapor deposition crucible 42c is set to, for example, 1015° C., and the temperature of the selenium (Se) vapor deposition crucible 42d is set to, for example, 270° C., by the power sources 44a to 44d.

Subsequently, after the vapor deposition crucibles 42a to 42d are in a state where they can produce vapors of Cu, In, Ga and Se, the shutters 46a to 46d are opened at the same time, and film deposition is carried out for 1 minute, for example.

Subsequently, when 1 minute has elapsed after simultaneously opening the shutters 46a to 46d, the shutter 46b of the indium (In) vapor deposition crucible 42b is closed, and film deposition is carried out for 4 minutes.

Subsequently, when 4 minutes have elapsed, the shutter 46b of the indium (In) vapor deposition crucible 42b is opened, and film deposition is carried out for 5 minutes.

Subsequently, when 5 minutes have elapsed, the shutter 46a of the copper (Cu) vapor deposition crucible 42a is closed, and film deposition is carried out for 5 minutes.

As a result, the film formation time is 15 minutes, but by adjusting the amount of vapor deposition of copper (Cu) and the amount of vapor deposition of indium (In) by opening and closing the shutters, the Ga/(In+Ga) ratio as of the initial stage of formation of the photoelectric conversion layer is reduced, and a CIGS layer in which the Ga/(In+Ga) ratio varies in the direction of thickness can be formed as the photoelectric conversion layer 16.

Thus, in this embodiment, even if the formation step of the CIGS layer serving as the photoelectric conversion layer 16 is accomplished in less than 40 minutes, a CIGS layer in which the Ga/(In+Ga) ratio varies in the direction of thickness can be formed. As a result, photoelectric conversion efficiency can be improved by varying the bandgap (Eg) in the direction of thickness of the CIGS layer. For this reason, a photoelectric conversion element and thin-film solar cell with high photoelectric conversion efficiency can be obtained. Moreover, because the formation time of the photoelectric conversion layer 16 is short, energy costs such as the energy required for heating can be reduced, and production efficiency can be increased.

Further, as the substrate 12, a substrate with an insulation layer in which an anodized film having a porous structure 5 μm in thickness has been formed on the surface of JIS 1N99 material (purity 99.99 mass %) 300 μm in thickness may be used, and the photoelectric conversion layer 16 may be formed after forming a molybdenum film 800 nm in thickness, for example, as a back electrode on the surface of this substrate with an insulation layer.

Additionally, as the substrate 12, a polyimide base 0.3 mm in thickness may be used, and the photoelectric conversion layer 16 may be formed after forming a molybdenum film 800 nm in thickness, for example, as a back electrode on this polyimide base.

As described above, if a substrate having flexibility, such as a polyimide base or substrate with an insulation layer, is used as the substrate 12, the photoelectric conversion layer 16 may be formed using the roll-to-roll process. In this case, a roll-to-roll process film deposition apparatus may be used instead of the film deposition apparatus 30 illustrated in FIG. 2. When a roll-to-roll process film deposition apparatus is used, a copper (Cu) vapor deposition crucible, an indium (In) vapor deposition crucible, a gallium (Ga) vapor deposition crucible and a selenium (Se) vapor deposition crucible having different amounts of vapor deposition, for example, are arranged, and the Ga/(In+Ga) ratio can be varied over time.

The method for forming the photoelectric conversion layer 16 is not limited to the production method described above. For example, the photoelectric conversion layer 16 may be formed by varying the amount of vapor deposition of Cu, In and Ga by varying the temperatures of the vapor deposition crucibles 42a to 42d.

In this case, the temperature of the copper (Cu) vapor deposition crucible 42a is set to, for example, 1300° C., the temperature of the indium (In) vapor deposition crucible 42b is set to, for example, 870° C., the temperature of the gallium (Ga) vapor deposition crucible 42c is set to, for example, 1015° C., and the temperature of the selenium (Se) vapor deposition crucible 42d is set to, for example, 270° C., by the power sources 44a to 44d.

Note that from the start of film deposition, the temperature setting of the copper (Cu) vapor deposition crucible 42a is decreased by, for example, 10° C./minute, the temperature setting of the indium (In) vapor deposition crucible 42b is increased by, for example, 6° C./minute, the temperature setting of the gallium (Ga) vapor deposition crucible 42c is decreased by, for example, 3° C./minute, and the temperature setting of the selenium (Se) vapor deposition crucible 42d is constant.

Subsequently, after it is in a state where vapors of Cu, In, Ga and Se can be produced from the vapor deposition crucibles 42a to 42d, the shutters 46a to 46d are opened at the same time, and film deposition is carried out for 15 minutes, for example. In this production method as well, the Ga/(In+Ga) ratio is reduced from that as of the initial stage of formation of the photoelectric conversion layer, and a CIGS layer in which the Ga/(In+Ga) ratio varies in the direction of thickness can be formed as the photoelectric conversion layer 16.

In this case as well, a photoelectric conversion element and thin-film solar cell having excellent photoelectric conversion efficiency can be obtained, and moreover, a photoelectric conversion element and thin-film solar cell can be obtained with reduced energy costs and high production efficiency.

Additionally, opening and closing of the shutters 46a to 46d and variation of the temperatures of the vapor deposition crucibles 42a to 42d described above may be combined. In this case, the temperature of the copper (Cu) vapor deposition crucible 42a is set to, for example, 1300° C., the temperature of the indium (In) vapor deposition crucible 42b is set to, for example, 870° C., the temperature of the gallium (Ga) vapor deposition crucible 42c is set to, for example, 1015° C., and the temperature of the selenium (Se) vapor deposition crucible 42d is set to, for example, 270° C., by the power sources 44a to 44d.

Note that the temperature of the copper (Cu) vapor deposition crucible 42a and the temperature of the selenium (Se) vapor deposition crucible 42d remain constant from the start of film deposition. The temperature of the indium (In) vapor deposition crucible 42b is increased by, for example, 6° C./minute, and the temperature of the gallium (Ga) vapor deposition crucible 42c is decreased by, for example, 3° C./minute.

Subsequently, after it is in a state where vapors of Cu, In, Ga and Se can be produced from the vapor deposition crucibles 42a to 42d, the shutters 46a to 46d are opened at the same time, and film deposition is carried out for 10 minutes, for example.

Subsequently, when 10 minutes have elapsed after simultaneously opening the shutters 46a to 46d, the shutter 46a of the copper (Cu) vapor deposition crucible 42a is closed, and film deposition is carried out for 5 minutes.

In this method for manufacturing a photoelectric conversion layer 16 as well, the Ga/(In+Ga) ratio is reduced from that as of the initial stage of formation of the photoelectric conversion layer, and a CIGS layer in which the Ga/(In+Ga) ratio varies in the direction of thickness can be formed as the photoelectric conversion layer 16. As a result, a photoelectric conversion element and thin-film solar cell having excellent photoelectric conversion efficiency can be obtained, and moreover, a photoelectric conversion element and thin-film solar cell can be obtained with reduced energy costs and high production efficiency.

The CIGS layers formed by the above three methods have a single-graded structure.

Note that a photoelectric conversion layer 16 wherein the Ga distribution decreases in the direction of thickness of the CIGS layer and then increases above the decreased state, that is, a CIGS layer having a double-graded structure, may be produced as follows.

Specifically, the temperature of the copper (Cu) vapor deposition crucible 42a is set to, for example, 1300° C., the temperature of the indium (In) vapor deposition crucible 42b is set to, for example, 870° C., the temperature of the gallium (Ga) vapor deposition crucible 42c is set to, for example, 1015° C., and the temperature of the selenium (Se) vapor deposition crucible 42d is set to, for example, 270° C., by the power sources 44a to 44d.

Note that from the start of film deposition, the temperature setting of the copper (Cu) vapor deposition crucible 42a is decreased by, for example, 10° C./minute, the temperature setting of the indium (In) vapor deposition crucible 42b is increased by, for example, 6° C./minute, the temperature setting of the gallium (Ga) vapor deposition crucible 42c is decreased by, for example, 3° C./minute, and the temperature setting of the selenium (Se) vapor deposition crucible 42d is constant.

Subsequently, after it is in a state where vapors of Cu, In, Ga and Se can be produced from the vapor deposition crucibles 42a to 42d, the shutters 46a to 46d are opened at the same time, and film deposition is carried out for 7 minutes 30 seconds, for example.

Subsequently, after film deposition for 7 minutes 30 seconds, the temperature of the copper (Cu) vapor deposition crucible 42a is set to, for example, 1250° C., the temperature of the indium (In) vapor deposition crucible 42b is set to, for example, 900° C., the temperature of the gallium (Ga) vapor deposition crucible 42c is set to, for example, 1000° C., and the temperature of the selenium (Se) vapor deposition crucible 42d is set to, for example, 270° C., by the power sources 44a to 44d.

After film deposition for 7 minutes 30 seconds, the temperature setting of the copper (Cu) vapor deposition crucible 42a is decreased by, for example, 10° C./minute, the temperature setting of the indium (In) vapor deposition crucible 42b is decreased by, for example, 6° C./minute, the temperature setting of the gallium (Ga) vapor deposition crucible 42c is increased by, for example, 3° C./minute, and the temperature setting of the selenium (Se) vapor deposition crucible 42d is constant. Under such conditions, film deposition is performed for, for example, 7 minutes 30 seconds.

A photoelectric conversion layer 16 having a Ga distribution such that the Ga/(In+Ga) ratio is decreased from that as of the initial stage of formation of the photoelectric conversion layer 16 and then increased above the decreased state, that is, a CIGS layer having a double-graded structure, may be formed by the above method for manufacturing the photoelectric conversion layer 16.

By this method for manufacturing a photoelectric conversion layer as well, a photoelectric conversion element and thin-film solar cell having excellent photoelectric conversion efficiency can be obtained, and moreover, a photoelectric conversion element and thin-film solar cell can be obtained with reduced energy costs and high production efficiency.

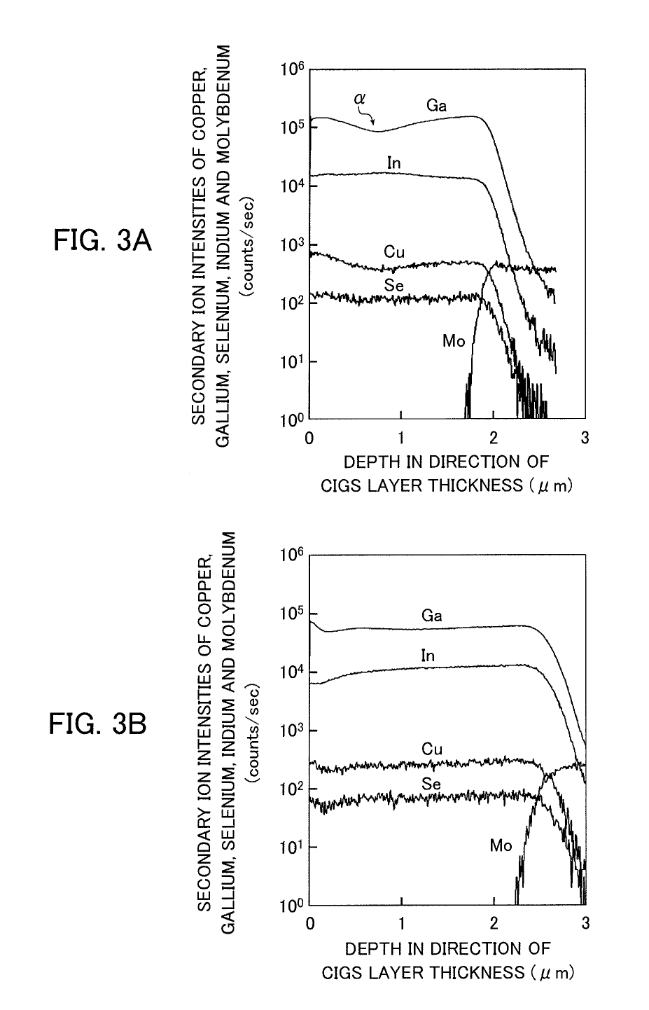

Analysis by SIMS (secondary ion mass spectrometry) was performed on a double-graded CIGS layer formed using the method for manufacturing a photoelectric conversion layer described above of the photoelectric conversion element having the CIGS layer (referred to as “photoelectric conversion element of the present invention” hereinafter) to obtain the secondary ion intensity of copper(Cu), gallium(Ga), selenium(Se), indium(In) and molybdenum(Mo). The results are shown in FIG. 3A.

Further, for comparison, the temperature of the copper (Cu) vapor deposition crucible 42a was set to, for example, 1300° C., the temperature of the indium (In) vapor deposition crucible 42b was set to, for example, 870° C., the temperature of the gallium (Ga) vapor deposition crucible 42c was set to, for example, 1015° C., and the temperature of the selenium (Se) vapor deposition crucible 42d was set to, for example, 270° C., and a CIGS layer was formed without varying the amount of vapor deposition from the vapor deposition crucibles 42a to 42d. A photoelectric conversion element having this CIGS layer (referred to as “conventional photoelectric conversion element” hereinafter) was produced. Analysis by SIMS (secondary ion mass spectrometry) was also performed on the CIGS layer of the conventional photoelectric conversion element to obtain the secondary ion intensity of copper, gallium, selenium, indium and molybdenum. The results are shown in FIG. 3B.

In FIGS. 3A and 3B, the position at a depth of 0 μm in the direction of the thickness of the CIGS layer indicates the surface of the CIGS layer.

As shown in FIG. 3A, in the CIGS layer of the photoelectric conversion element of the present invention, the secondary ion intensity of Ga decreased and then increased, as in region a.

Note that the proportion of the minimum Ga ion count with respect to the maximum was 60% in the photoelectric conversion element of the invention.

On the other hand, in the CIGS layer of the conventional photoelectric conversion element, the secondary ion intensity of Ga was substantially flat as illustrated in FIG. 3B. Note that the proportion of the minimum Ga ion count with respect to the maximum was 85% in the conventional photoelectric conversion element.

Additionally, the photoelectric conversion element of the present invention and the conventional photoelectric conversion element were assessed for photoelectric conversion efficiency (η) using artificial sun light of 100 mW/cm² and air mass (AM) of 1.5, fill factor (FF), open-circuit voltage (Voc) and short-circuit current density (Jsc). The results are shown in Table 1. As shown in Table 1, the photoelectric conversion efficiency of the photoelectric conversion element of the present invention is higher than that of the conventional photoelectric conversion element.

TABLE 1

| | Photoelectric | |
|---|---|---|
| | conversion element | conventional |
| | of the present | photoelectric |
| | invention | conversion element |
| η ( % ) | 15.8 | 14.3 |
| FF | 0.73 | 0.718 |
| Voc (V) | 0.684 | 0.672 |
| Jsc (mA/cm²) | 31.58 | 29.71 |
| Effective area | 0.96 | 0.96 |
| (cm²) | | |

The present invention is basically as described above. While the method for manufacturing a photoelectric conversion element, the photoelectric conversion element and the thin-film solar cell of the present invention have been described above in detail, the present invention is by no means limited to the above embodiments, and various improvements or design modifications may be made without departing from the scope and spirit of the present invention.

1. A method for manufacturing a photoelectric conversion element comprising the steps of:
preparing a substrate, and
forming a photoelectric conversion layer made of a CIGS-based semiconductor compound on the substrate,
wherein the step of forming the photoelectric conversion layer comprises exposing the substrate to vapors of (In, Ga) and Se, or vapor of (In, Ga)_{y}Se_{z} and is accomplished in less than 40 minutes; and the step of exposing the substrate to vapors of (In, Ga) and Se, or vapor of (In, Ga)_{y}Se_{z} includes varying a Ga/(In+Ga) ratio over time.

2. The method of manufacturing a photoelectric conversion element according to claim 1, wherein the step of forming the photoelectric conversion layer is carried out in a temperature range of 500° C. to 650° C.

3. The method of manufacturing a photoelectric conversion element according to claim 1, wherein varying the Ga/(In+Ga) ratio over time in the step of exposing the substrate to vapors of (In, Ga) and Se, or vapor of (In, Ga)_{y}Se_{z} means reducing the Ga/(In+Ga) ratio as of the initial stage of formation of the photoelectric conversion layer.

4. The method of manufacturing a photoelectric conversion element according to claim 1, wherein varying the Ga/(In+Ga) ratio over time in the step of exposing the substrate to vapors of (In, Ga) and Se, or vapor of (In, Ga)_{y}Se_{z} means reducing and then increasing the Ga/(In+Ga) ratio as of the initial stage of formation of the photoelectric conversion layer.

5. The method of manufacturing a photoelectric conversion element according to claim 1, wherein the substrate is an insulating substrate.

6. The method of manufacturing a photoelectric conversion element according to claim 5, wherein the insulating substrate is a glass sheet, a glass sheet coated with molybdenum, an anodized aluminum sheet, a base in which the anodized film of an anodized aluminum sheet is coated with molybdenum, or a polyimide base or polyimide base coated with molybdenum.

7. A method for manufacturing a photoelectric conversion element comprising steps of:
preparing a substrate, and
forming a photoelectric conversion layer made of a CIGS-based semiconductor compound on the substrate,
wherein the step of forming the photoelectric conversion layer includes a first step of forming a phase-separated compound mixture made of Cu(In, Ga)Se₂: CuₓSe containing a large amount of Cu on the substrate, and a second step of transforming CuₓSe to Cu_{w}(In, Ga)_{y}Se_{z} by exposing the CuₓSe in the phase-separated compound mixture to vapors of (In, Ga) and Se, or by exposing the CuₓSe in the phase-separated compound mixture to vapor of (In, Ga)_{y}Se_{z},
wherein the step of forming the photoelectric conversion layer is accomplished in less than 40 minutes, and
wherein the second step includes varying the Ga/(In+Ga) ratio over time.

8. The manufacturing method of a photoelectric conversion element according to claim 7, wherein in the second step, varying the Ga/(In+Ga) ratio over time means reducing the Ga/(In+Ga) ratio as of the initial stage of formation of the photoelectric conversion layer.

9. The manufacturing method of a photoelectric conversion element according to claim 7, wherein, in the second step, varying the Ga/(In+Ga) ratio over time means reducing and then increasing the Ga/(In+Ga) ratio as of the initial stage of formation of the photoelectric conversion layer.

10. The method of manufacturing a photoelectric conversion element according to claim 7, wherein the first step is carried out in a temperature range of 500° C. to 650° C.

11. The manufacturing method of a photoelectric conversion element according to claim 7, wherein the second step is carried out in a temperature range of 500° C. to 650° C.

12. The method of manufacturing a photoelectric conversion element according to claim 7, wherein the second step includes a step of transforming the CuₓSe to Cu(In, Ga)Se₂.

13. The method of manufacturing a photoelectric conversion element according to claim 7, wherein in the CuₓSe, x is in a range such that 1≦x≦2.

14. The method of manufacturing a photoelectric conversion element according to claim 7, wherein the ratio of Cu(In, Ga)Se₂: CuₓSe is 1:2.

15. The method of manufacturing a photoelectric conversion element according to claim 7, wherein a compound mixture made of Cu(In, Ga)Se₂: CuₓSe has a Cu content of 40 atomic % to 50 atomic %.

16. The method of manufacturing a photoelectric conversion element according to claim 7, wherein the second step includes a step of exposing the CuₓSe to vapor of a In_{y}Se_{z}.

17. The method of manufacturing a photoelectric conversion element according to claim 16, wherein the second step includes a step of exposing the CuₓSe to vapor of a In₂Se₃.

18. The method of manufacturing a photoelectric conversion element according to claim 7, wherein the second step includes a step of exposing the CuₓSe to vapors of the Se and In.

19. The method of manufacturing a photoelectric conversion element according to claim 7, wherein the first step includes a step of producing the compound mixture by forming the Cu(In, Ga)Se₂ and the CuₓSe on the base.

20. The method of manufacturing a photoelectric conversion element according to claim 19, wherein the first step includes a step of producing the compound mixture by simultaneously forming the Cu(In, Ga)Se₂ and the CuₓSe on the base.

21. The method of manufacturing a photoelectric conversion element according to claim 19, wherein the first step includes a step of producing the compound mixture by sequentially forming the Cu(In, Ga)Se₂ and the CuₓSe on the base.

22. The method of manufacturing a photoelectric conversion element according to claim 7, wherein the first step includes a step of producing the compound mixture by forming the CuₓSe and In_{y}Se_{z}.

23. The method of manufacturing a photoelectric conversion element according to claim 22, wherein the first step includes a step of producing the compound mixture by sequentially forming the CuₓSe and In_{y}Se_{z}.

24. The method of manufacturing a photoelectric conversion element according to claim 22, wherein the first step includes a step of producing the compound mixture by simultaneously forming the CuₓSe and In_{y}Se_{z}.

25. The method of manufacturing a photoelectric conversion element according to claim 22, wherein in the CuₓSe, x is in a range such that 1≦x≦2, and in the In_{y}Se_{z}, y is 2 and z is 3.

26. The method of manufacturing a photoelectric conversion element according to claim 7, wherein the substrate is an insulating substrate.

27. The method of manufacturing a photoelectric conversion element according to claim 7, wherein the insulating substrate is a glass sheet, a glass sheet coated with molybdenum, an anodized aluminum sheet, a base in which the anodized film of an anodized aluminum sheet is coated with molybdenum, or a polyimide base or polyimide base coated with molybdenum.

28. A photoelectric conversion element produced according to a method of manufacturing a photoelectric conversion element described in claim 1.

29. A thin-film solar cell comprising a photoelectric conversion element according to claim 28.
